(19) United States
(12) Patent Application Publication
(10) Pub. No.: US 2012/0217461 A1
(43) Pub. Date: Aug. 30, 2012

(54) SEMICONDUCTOR MEMORY DEVICE AND METHOD OF MANUFACTURING THE SAME

(75) Inventors: Shigeki KOBAYASHI, Kuwana-shi (JP); Takashi Shigeoka, Fujisawa-shi (JP); Mitsuru Sato, Kuwana-shi (JP); Takahiro Hirai, Yokohama-shi (JP); Katsuyuki Sekine, Yokkaichi-shi (JP); Kazuya Kinoshita, Yokkaichi-shi (JP); Soichi Yamazaki, Yokkaichi-shi (JP); Ryota Fujitsuka, Yokkaichi-shi (JP); Kensuke Takahashi, Yokohama-shi (JP); Yasuhiro Nojiri, Yokkaichi-shi (JP); Masaki Yamato, Yokkaichi-shi (JP); Hiroyuki Fukumizu, Yokkaichi-shi (JP); Takeshi Yamaguchi, Kawasaki-shi (JP)

(73) Assignee: Kabushiki Kaisha Toshiba, Tokyo (JP)

(21) Appl. No.: 13/404,795

(22) Filed: Feb. 24, 2012

(30) Foreign Application Priority Data
Feb. 25, 2011 (JP) 2011-039485
Feb. 20, 2012 (JP) 2012-033769

(51) Int. Cl. H01L 45/00; H01L 21/8239; B82Y 99/00

(52) U.S. Cl. 257/2; 438/382; 257/E21.004; 977/943; 257/E45.003

(57) ABSTRACT

A semiconductor memory device according to an embodiment includes: first lines provided on a substrate; second lines provided between the first lines and the substrate so as to intersect the first lines; and a first memory cell array including first memory cells, each of the first memory cells being provided at respective intersections of the first lines and the second lines and including a current rectifying element and a variable resistor connected in series. The variable resistor of the first memory cell includes a first recording layer and a second recording layer, the first recording layer being made of an oxide of a first metal material, the second recording layer being made of the first metal material and being formed so as to contact with the first recording layer. The second recording layer is closer to the first line than the first recording layer is.

### CROSS REFERENCE TO RELATED APPLICATION

This application is based upon and claims the benefit of priority from prior Japanese Patent Application No. 2011-39485, filed on Feb. 25, 2011, and Japanese Patent Application No. 2012-33769, filed on Feb. 20, 2012, the entire contents of which are incorporated herein by reference.

### BACKGROUND

1. Field

Embodiments described herein relate to a semiconductor memory device including memory cells that store data using a change in the resistance value of a variable resistor and a method of manufacturing the same.

2. Description of the Related Art

In recent years, a resistance change memory device using a variable resistor as a memory element draws attention as a candidate to succeed the flash memory. It is assumed that the resistance change memory device includes a resistance change memory (ReRAM: Resistive RAM) in its narrow definition, in which a recording layer is made of transition metal oxide and a resistance-value state of the recording layer is stored in a nonvolatile manner, and a phase change memory (PCRAM: Phase Change RAM), in which the recording layer is made of chalcogenide or the like and resistance value information of a crystal state (conductor) and an amorphous state (insulator) of the recording layer are utilized.

In order to achieve a high-density memory cell array, it is preferable to manufacture a memory cell array in which a variable resistor and a current rectifying element, such as a diode, are provided at an intersection of a bit line and a word line, and the current rectifying element, such as a diode, is used to select a bit, without providing one transistor for each bit and using the transistor to select the bit. It is preferable that the bit lines and the word lines are alternately stacked to three-dimensionally arrange the memory cell array. In the high density memory cell array which is three-dimensionally stacked and arranged, it is preferable that peripheral circuits connected to the bit lines and those connected to the word lines which intersect each other have different functions for the bit lines and the word lines, respectively. In this case, the redundancy of the peripheral circuits can be minimized, and the area of the peripheral circuits can be reduced. As a result, a memory device which has a small area is achieved while maintaining the memory capacity. Therefore, as described above, in the memory device in which the memory cell array including the variable resistors and the current rectifying elements, such as diodes, provided at the intersections of the bit lines and the word lines is three-dimensionally stacked and arranged, it is preferable that the current rectification directions of the current rectifying element are changed, depending on the stacked order of the bit line and the word line. The current rectifying direction when the bit line is disposed above the word line is different from that when the bit line is disposed below the word line.

In general, the resistance change film fabricated in a not-well-controlled manufacturing process is likely to have a composition gradient in the direction perpendicular to the surface. This composition gradient sometimes leads to insufficient performances of memory cells such as insufficient data retention characteristics. As mentioned above, in order to reduce the unnecessary redundancy of the peripheral circuits, the current rectification directions of the current rectifying element provided at the intersection of the bit line and the word line may be changed according to the stacked order of the bit line and the word line dimensionally stacking and arranging. The current rectifying direction when the bit line is disposed above the word line is different from that when the bit line is disposed below the word line. In this case, it is necessary to control factors such as the local variation of material components in the resistance change film so that the data retention characteristics is sufficient, regardless of the current rectification direction of the current rectifying element.

### BRIEF DESCRIPTION OF THE DRAWINGS

FIG. 1 is a block diagram illustrating a semiconductor memory device according to a first embodiment of the present invention;

FIG. 2 is a perspective view illustrating a portion of a memory cell array 1;

FIG. 3 is a cross-sectional view illustrating one memory cell taken along the line I-I′ of FIG. 2, as viewed from the direction of an arrow;

FIG. 4 is a circuit diagram illustrating the memory cell array 1 and peripheral circuits thereof;

FIG. 5 is cross-sectional view illustrating the configuration of a memory cell according to a comparative example;

FIG. 6 is graph illustrating the data retention characteristics of the memory cell according to the comparative example;

FIG. 7 is a cross-sectional view illustrating the configuration of a memory cell according to the first embodiment;

FIG. 8 is a process diagram illustrating a method of manufacturing the memory cell according to the first embodiment;

FIG. 9 is a perspective view illustrating a portion of a memory cell array 1 according to another example;

FIG. 10 is a cross-sectional view illustrating the memory cell taken along the line II-II′ of FIG. 9, as viewed from the direction of an arrow;

FIG. 11A is a cross-sectional view illustrating the configuration of a memory cell of a memory cell array 1 according to another example;

FIG. 11B is a cross-sectional view illustrating the configuration of a memory cell of a memory cell array 1 according to another example;

FIG. 12 is a cross-sectional view illustrating the configuration of a memory cell according to a second embodiment;

FIG. 13 is a process diagram illustrating a method of manufacturing the memory cell according to the second embodiment;

FIG. 14 is a cross-sectional view illustrating the configuration of a memory cell according to a third embodiment;

FIG. 15 is a process diagram illustrating a method of manufacturing the memory cell according to the third embodiment;

FIG. 16 is a process diagram illustrating a a method of manufacturing a memory cell according to another example;

FIG. 17 is a cross-sectional view illustrating the configuration of a memory cell according to a fourth embodiment;

FIG. 18 is a process diagram illustrating a method of manufacturing the memory cell according to the fourth embodiment;

FIG. 19 is a graph illustrating the data retention characteristics of the memory cell according to the fourth embodiment;

FIG. 20 is a graph illustrating the data characteristics of the memory cell retention according to the fourth embodiment;

FIG. 21 is a cross-sectional view illustrating the configuration of a memory cell of a memory cell array 1 according to another example;

FIG. 22 is a cross-sectional view illustrating the configuration of a memory cell according to a fifth embodiment;

FIG. 23 is a process diagram illustrating a method of manufacturing the memory cell according to the fifth embodiment;

FIG. 24 is a cross-sectional view illustrating the configuration of a memory cell according to a sixth embodiment; and

FIG. 25 is a process diagram illustrating a method of manufacturing the memory cell according to the sixth embodiment.

### DETAILED DESCRIPTION

A semiconductor memory device according to an embodiment includes: a plurality of first lines provided on a substrate; a plurality of second lines provided between the first lines and the substrate so as to intersect the first lines; and a first memory cell array including first memory cells, each of the first memory cells being provided at respective intersections of the first lines and the second lines and including a current rectifying element and a variable resistor connected in series. The variable resistor of the first memory cell includes a first recording layer and a second recording layer, the first recording layer being made of an oxide of a first metal material, the second recording layer being made of the first metal material and being formed so as to contact with the first recording layer. The second recording layer is closer to the first line than the first recording layer is.

Hereinafter, embodiments of the present invention will be described in detail with reference to the accompanying drawings. In the drawings according to the following embodiments, components having the same configurations are denoted by the same reference numerals and the redundant description thereof will be omitted.

[Entire Configuration]

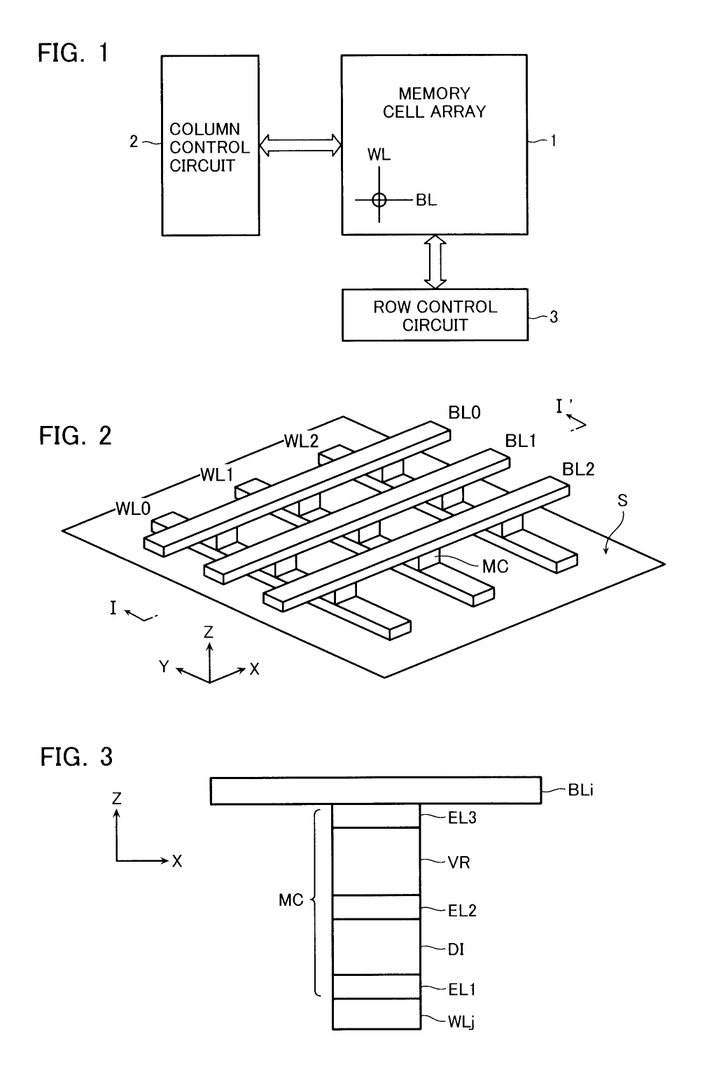

FIG. 1 is a block diagram illustrating the configuration of a non-volatile memory according to a first embodiment of the present invention. The non-volatile memory includes a memory cell array 1 in which memory cells using a resistance change film, which will be described below, are arranged in a matrix.

A column control circuit 2 is electrically connected to bit lines BL of the memory cell array 1 to control the voltage of the bit lines BL. The column control circuit 2 controls the voltage of the bit lines BL of the memory cell array 1 to erase data in the memory cells, write data to the memory cells, and read data from the memory cells. In addition, a row control circuit 3 is electrically connected to word lines WL of the memory cell array 1 to control the voltage of the word lines WL. The row control circuit 3 selects the word lines WL of the memory cell array 1 to erase data in the memory cells, write data to the memory cells, and read data from the memory cells.

[Memory Cell Array 1]

FIG. 2 is a perspective view illustrating a portion of the memory cell array 1, and FIG. 3 is a cross-sectional view illustrating one memory cell taken along the line I-I′ of FIG. 2, as viewed from the direction of an arrow. Word lines WL0 to WL2 are arranged as a plurality of first lines in the Y direction parallel to the surface of a semiconductor substrate S. Bit lines BL0 to BL2 are arranged as a plurality of second lines in the X direction parallel to the surface of the semiconductor substrate S so as to intersect the word lines WL0 to WL2. A memory cell MC is provided at each of the intersections of the word lines (from WL0 to WL2) and the bit lines (from BL0 to BL2) so as to be interposed therebetween. It is preferable that the first and second lines are made of a material having sufficient immunity to heat and a small resistance value. For example, the first and second lines may be made of W, WN, WSi, NiSi, or CoSi.

[Memory Cell MC]

As illustrated in FIG. 3, the memory cell MC is a circuit in which a variable resistor VR and a current rectifying element, such as a diode DI, are connected in series in the Z direction perpendicular to the semiconductor substrate S. The variable resistor VR is made of a material whose resistance value can be changed by, for example, an electric field, an electric current, heat, or chemical energy when a voltage is applied. Electrodes EL1, EL2, and EL3 that function as a barrier metal and/or an adhesive layer are provided above and/or below the variable resistor VR and the diode DI. The diode DI is arranged on the electrode EL1 and the electrode EL2 is arranged on the diode DI. The variable resistor VR is arranged on the electrode EL2 and the electrode EL3 is arranged on the variable resistor VR. The electrodes EL1, EL2, and EL3 may be made of, for example, a titanium nitride (TiN). Materials of the electrodes EL1, EL2, and EL3 may be different from each other. Other candidates for the electrodes EL1, EL2, and EL3, for example, may be Pt, Au, Ag, TiAlN, SrRuO, Ru, RuN, Ir, Co, Ti, TiN, TaN, LaNiO, Al, PtIrOₓ, PtRhOₓ, Rh, TaAlN, W, WN, TaSiN, TaSi₂, TiSi, TiC, TaC, Nb—TiO₂, NiSi, or CoSi. In addition, a metal film may be inserted to control the orientation of grain in the electrodes EL1, EL2, EL3, and/or the variable resistor VR. Moreover, a buffer layer, a barrier metal layer, or an adhesive layer may be inserted. A configuration in which the stacking order of the diode DI and the variable resistor VR in the Z direction is reversed is also included in the scope of the embodiment according to the present invention.

[Current Rectifying Element]

The current rectifying element used in the memory cell MC may be made of any material, and may have any structure as long as it has current rectifying characteristics in the voltage-current characteristics. For example, the diode DI made of polysilicon (Poly-Si) is used as the current rectifying element. One example of the diode DI is a PN-junction diode which consists of polysilicon containing different impurities to form p-type and n-type doped layers. In addition to the PN-junction diode, various kinds of structures, such as a Schottky diode or a PIN diode in which a non-doped layer is inserted between a p-type doped layer and a n-type doped layer, or a punch through diode may be used as the diode DI. Furthermore, in order to obtain the current rectifying characteristics which makes it possible to supply a certain voltage and current to a resistance change film of a selected memory cell MC, the current rectifying element may be made of various materials, such as silicon germanium, germanium, compound semiconductors, or any composition of a semiconductor, a metal, and an insulating material.

In order to write data to the memory cell MC, a certain voltage is applied to the variable resistor VR of the selected memory cell MC for a certain period of time. Then, the variable resistor VR of the selected memory cell MC is changed from a high resistance state to a low resistance state. Hereinafter, an operation of changing the variable resistor VR from the high resistance state to the low resistance state is referred to as a set operation. In order to erase data in the memory cell MC, a certain voltage in a certain direction is applied to the variable resistor VR in the low resistance state after the set operation for a certain period of time. Then, the variable resistor VR is changed from the low resistance state to the high resistance state. Hereinafter, an operation of changing the variable resistor VR from the low resistance state to the high resistance state is referred to as a reset operation. The memory cell MC adopts, for example, the high-resistance state as a stable state (reset state), and, in the case of binary data storage, write of data is performed by the set operation in which the reset state is changed to the low-resistance state.

[Memory Cell Array and Peripheral Circuits Thereof]

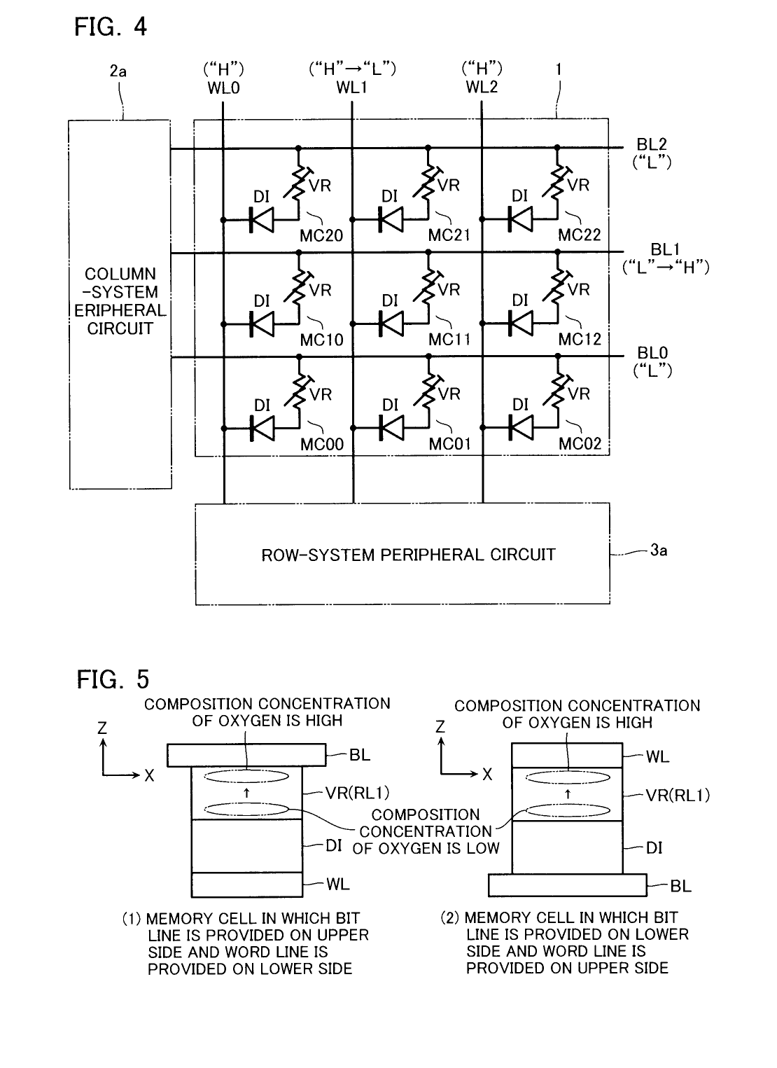

FIG. 4 is a circuit diagram illustrating the memory cell array 1 and the peripheral circuits thereof. In FIG. 4, the memory cell MC includes the variable resistor VR and the diode DI. The diode DI has current rectifying characteristics so that electric current flows from a selected bit line BL to a selected word line WL through a selected memory cell MC in the reset operation. In the set operation, current may flow from the word line WL to the bit line BL through the memory cell MC (bipolar operation), or current may flow from the bit line BL to the word line WL through the memory cell MC (unipolar operation). One end of each bit line BL is connected to a column-system peripheral circuit 2a, which is a portion of the column control circuit 2. One end of each word line WL is connected to a row-system peripheral circuit 3a, which is a portion of the row control circuit 3. The column-system peripheral circuit 2a and the row-system peripheral circuit 3a supply the voltage required for operations to the bit lines BL and the word lines WL. Different functions required for controlling the operations of the bit lines BL and the word lines WL may be added to the column-system peripheral circuit 2a and the row-system peripheral circuit 3a. In this case, the column-system peripheral circuit 2a and the row-system peripheral circuit 3a do not need to have the same configuration, but may have only the configuration used to control the operations of the bit lines BL and the word lines WL. Therefore, it is possible to minimize the area of the peripheral circuits.

Before the configuration of the variable resistor VR according to the first embodiment is described, the configuration of the variable resistor VR according to a comparative example will be described first. FIG. 5 is cross-sectional view illustrating the configuration of a memory cell array according to the comparative example. In the comparative example illustrated in FIG. 5, a variable resistor VR includes only one metal oxide layer made of, for example, a hafnium oxide (HfOₓ) as a first recording layer RL1. In FIG. 5, electrodes EL are not illustrated, but have the same configuration as described above. FIG. 5 (1) shows a memory cell MC in which a bit line BL is formed at the upper part of the memory cell MC in the Z direction and a word line WL is formed at the lower part thereof. FIG. 5 (2) shows a memory cell MC in which the word line WL is formed at the upper part of the memory cell MC in the Z direction and the bit line BL is formed at the lower part thereof. A diode DI has current rectifying characteristics in the direction in which electric current flows from the bit line BL to the word line WL through the variable resistor VR in the reset operation. That is, the current rectification direction of the diode DI in FIG. 5 (1) is different from that in FIG. 5 (2).

For the first recording layer RL1, a hafnium film is deposited and is then oxidized, thereby forming a hafnium oxide. Therefore, in the first recording layer RL1, the amount of oxygen per unit volume is smaller in a lower region (a region close to the semiconductor substrate S) in the Z direction (the composition concentration of oxygen is lower) and the amount of oxygen per unit volume is larger in an upper region (a region away from the semiconductor substrate S) in the Z direction (the composition concentration of oxygen is higher).

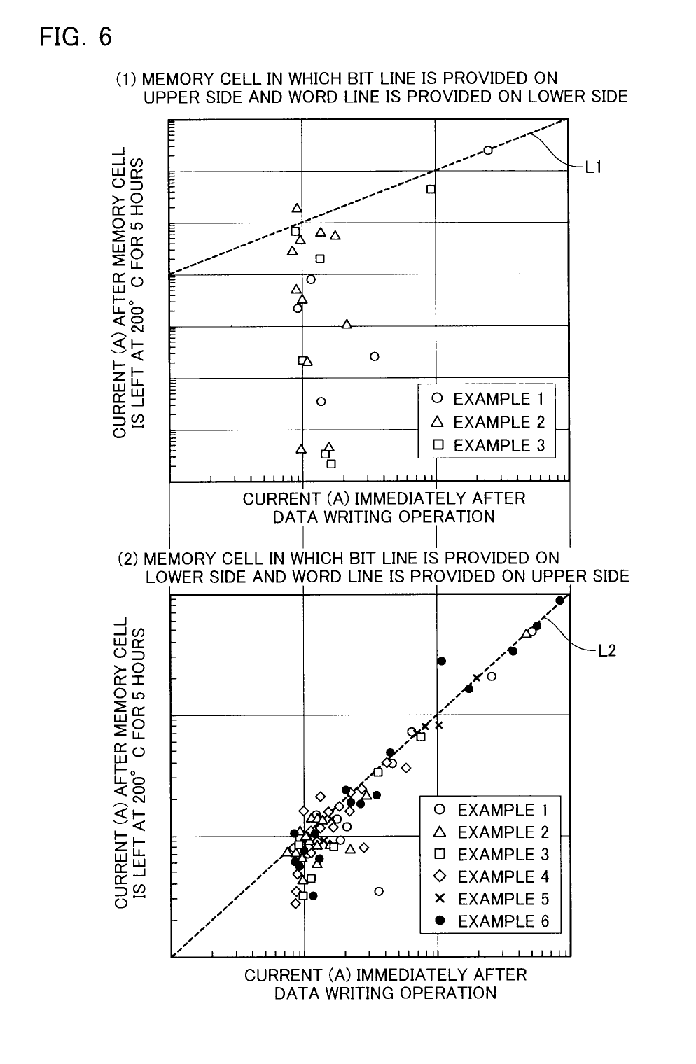

FIG. 6 is graph illustrating current characteristics when voltage is applied to the memory cell MC according to the comparative example. The graph illustrated in FIG. 6 (1) relates to the memory cell MC in which the bit line BL is formed at the upper part of the memory cell MC in the Z direction and the word line WL is formed at the lower part thereof. The graph illustrated in FIG. 6 (2) relates to the memory cell MC in which the word line WL is formed at the upper part of the memory cell MC in the Z direction and the bit line BL is formed at the lower part thereof. In the graphs illustrated in FIG. 6, the horizontal axis indicates the value of the current of the memory cell MC when a read voltage is applied to the memory cell MC immediately after data is written to the memory cell MC. In the graphs illustrated in FIG. 6, the vertical axis indicates the value of the current of the memory cell MC when a read voltage is applied to the memory cell. MC after a data write operation followed by a bake at 200° C. for 5 hours. In FIG. 6 (1) and FIG. 6 (2), the scale of the horizontal axis (the absolute values of the current) is the same, as shown with the vertical lines connected FIG. 6 (1) and FIG. 6 (2). As a guide, the current which is the same in both the vertical and horizontal axes is shown with the dashed line L1 and L2 in FIG. 6(1) and FIG. 6(2). Thus, measured data plotted on the dashed lines L1 and L2 means that the current of the memory cell MC read after the bake at 200° C. for 5 hours is the same as that read immediately after the data write operation. In examples 1 to 6 illustrated in FIG. 6, the thicknesses of the first recording layer RL1 and the manufacturing conditions of the electrode EL3 are changed. In general, in order to evaluate the reliability of the memory cell MC in a short time, a bake at high temperature is used to accelerate the deterioration of the memory cell MC. Here, data retention characteristics, which is one of the reliability properties of the memory cell MC, is investigated at a high temperature of 200° C. That is, if the data retention characteristics is sufficient, it is expected that the current of the memory cell MC will not be changed even after the memory cell MC is baked at 200° C. for 5 hours.

As shown in FIG. 6 (1), in the memory cell MC in which the word line WL is formed on the lower side in the Z direction and the bit line BL is formed on the upper side in the Z direction, the value of the current of the memory cell MC read after the 5 hours bake at 200° C. is less than that of the memory cell MC read immediately after the data write operation. In many cases, the change in the value of the current is equal to or more than one digit. On the other hand, as shown in FIG. 6 (2), in the memory cell MC in which the bit line BL is formed on the lower side in the Z direction and the word line WL is formed on the upper side in the Z direction, the value of the current of the memory cell MC read after the 5 hours bake at 200° C. is almost the same as that of the memory cell MC read immediately after the data write operation. Thus, when the bit line BL is formed on the lower side in the Z direction and the word line WL is formed on the upper side in the Z direction, the data retention characteristics is improved.

As described above, the first recording layer RL1 is formed so that the amount of oxygen per unit volume is smaller in the lower region (the region close to the semiconductor substrate S) in the Z direction and the amount of oxygen per unit volume is larger in the upper region (the region away from the semiconductor substrate S) in the Z direction. In addition, since the diode DI of the memory cell MC according to the comparative example has current rectifying characteristics by which current flows from the bit line BL to the word line WL through the first recording layer RL1, the bit line BL and the word line WL act as the positive electrode (Anode) and the negative electrode (Cathode) in the first recording layer RL1, respectively. Therefore, it is considered that the data retention characteristics is improved in the structure where the amount of oxygen is small in a portion of the first recording layer RL1 which is close to the positive electrode (Anode). The above is new findings obtained from the thorough experiments conducted by the inventors.

[Variable Resistor VR]

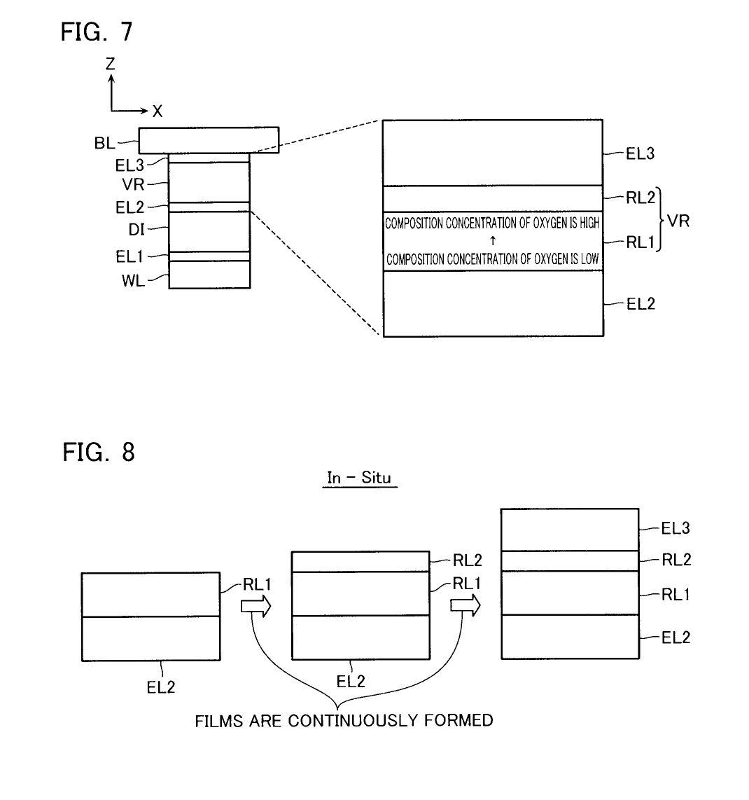

The memory cell MC according to the first embodiment has the following configuration of the variable resistor VR following to the experimental results explained above. Next, the detailed configuration of the variable resistor VR of the memory cell MC according to the embodiment will be described with reference to FIG. 7. FIG. 7 is a cross-sectional view illustrating the configuration of the memory cell MC and the variable resistor VR according to the embodiment. As described above, the memory cell MC includes the current rectifying element, such as the diode DI, the variable resistor VR, and the electrodes EL1 to EL3 connected in series.

As illustrated in FIG. 7, the variable resistor VR according to the embodiment includes a first recording layer RL1 made of a metal oxide and a second recording layer RL2 made of the same metal material but less oxidized, comparing to the first recording layer RL1. The first recording layer RL1 and the second recording layer RL2 are stacked in the Z direction perpendicular to the semiconductor substrate S. In the variable resistor VR, the second recording layer RL2 made of a metal material is closer to the bit line BL than the first recording layer RL1. The second recording layer RL2 is connected to the bit line BL through the electrode EL3. As described above, the electrodes EL2 and EL3 are formed above and below the variable resistor VR, respectively. The electrode EL3 is connected to the upper bit line BL and the electrode EL2 is connected to the word line WL through the lower diode DI. The electrodes EL2 and EL3 may be made of, for example, a titanium nitride (TiN).

The first recording layer RL1 and the second recording layer RL2 may be made of, for example, hafnium oxide (HfOₓ) and hafnium (Hf), respectively. In other examples, the combination of the first recording layer RL1 and the second recording layer RL2 may be manganese dioxide (MnO₂) and manganese, titanium oxide (TiOₓ) and titanium, niobium oxide (NbOₓ) and niobium, alumina (Al₂O₃) and aluminum, aluminum oxide (AlOₓ) and aluminum, nickel oxide (NiO) and nickel, or tungsten oxide (WO) and tungsten.

[Method of Manufacturing Variable Resistor VR]

Next, a method of manufacturing the variable resistor VR will be described with reference to FIG. 8. FIG. 8 is a diagram illustrating the method of manufacturing the variable resistor VR according to the embodiment. First, the word line WL, the electrodes EL1 and EL2, and the diode DI below the variable resistor VR are sequentially deposited by a known semiconductor device manufacturing method, and a certain stacked structure is formed (not illustrated). Then, the first recording layer RL1, the second recording layer RL2, and the electrode EL3 are sequentially formed on the electrode EL2. At that time, the first recording layer RL1, the second recording layer RL2, and the electrode EL3 are continuously formed in the same atmosphere so as not to be affected by an external environment, such as a manufacturing environment. Then, the bit line BL is formed thereon by a known semiconductor device manufacturing method, and a certain stacked structure is formed (not illustrated).

[Effect]

The memory cell MC according to the embodiment illustrated in FIG. 7 includes the first recording layer RL1 and the second recording layer RL2 which contain the same metal material and are stacked in this order in the Z direction, following to the experimental results explained above. Current flows from the bit line BL to the word line WL through the memory cell MC in the reset operation. In addition, the bit line BL is formed at the upper part of the memory cell MC in the Z direction, and the word line WL is formed at the lower part of the memory cell MC in the Z direction. In this way, in the variable resistor VR, there is a gradient of oxygen amount, and the less amount of oxygen exists in the upper part of the variable resistor VR which is close to the bit line BL. Following to the experimental results explained above, it is possible to improve the data retention characteristics of the memory cell MC in the configuration of the present embodiment.

[Other Examples of Memory Cell Array]

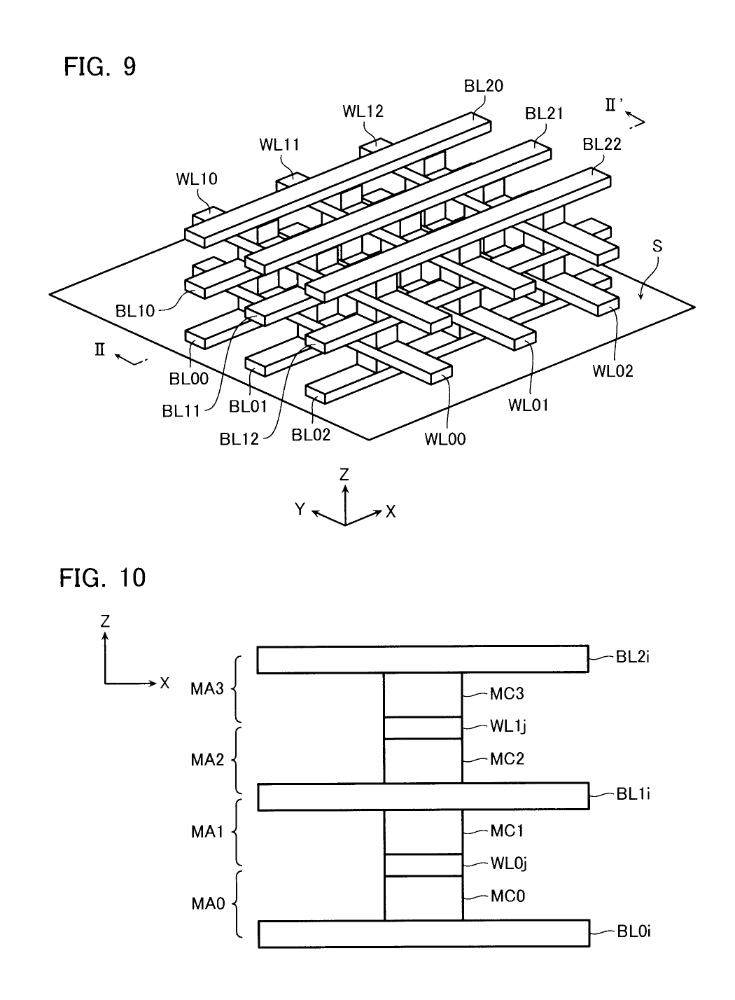

As illustrated in FIG. 9, a plurality of memory cell structures may be stacked in the Z direction to form a three-dimensional structure. FIG. 10 is a cross-sectional view illustrating the cross section taken along the line II-II′ of FIG. 9. In the example illustrated in FIGS. 9 and 10, a memory cell array has a four-layer structure including cell array layers MA0 to MA3. A word line WL0j is shared by memory cells MC0 and MC1 which are formed below and above the word line WL0j, respectively. A bit line BL1i is shared by the memory cells MC1 and MC2 which are formed below and above the bit line BL1i, respectively. A word line WL1j is shared by the memory cells MC2 and MC3 which are formed below and above the word line WL1j, respectively.

The memory cell array 1 may be divided into several memory cell groups MAT. The column control circuit 2 and the row control circuit 3 may be provided for each memory cell group MAT or each cell array layer MA, or they may be shared by the memory cell groups or the cell array layers. In addition, in order to reduce the area of the column control circuit 2, the same control circuit 2 may be used to control the different bit lines BL.

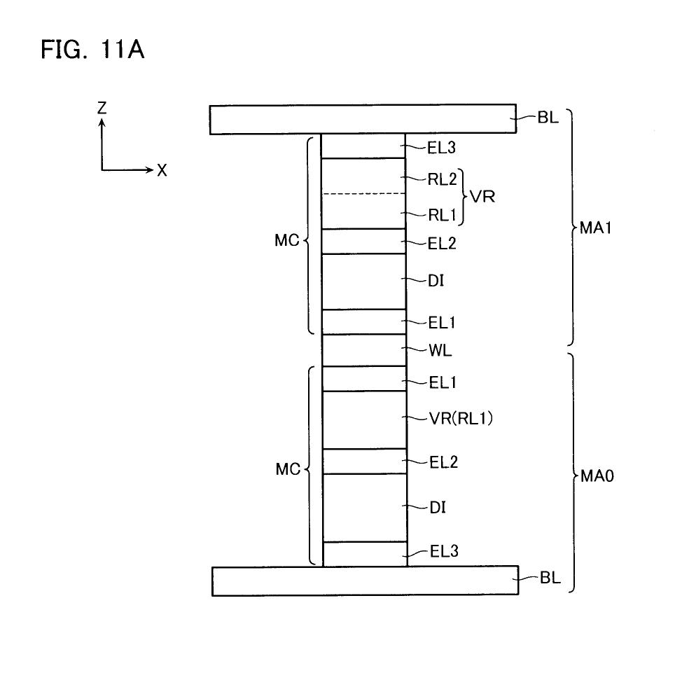

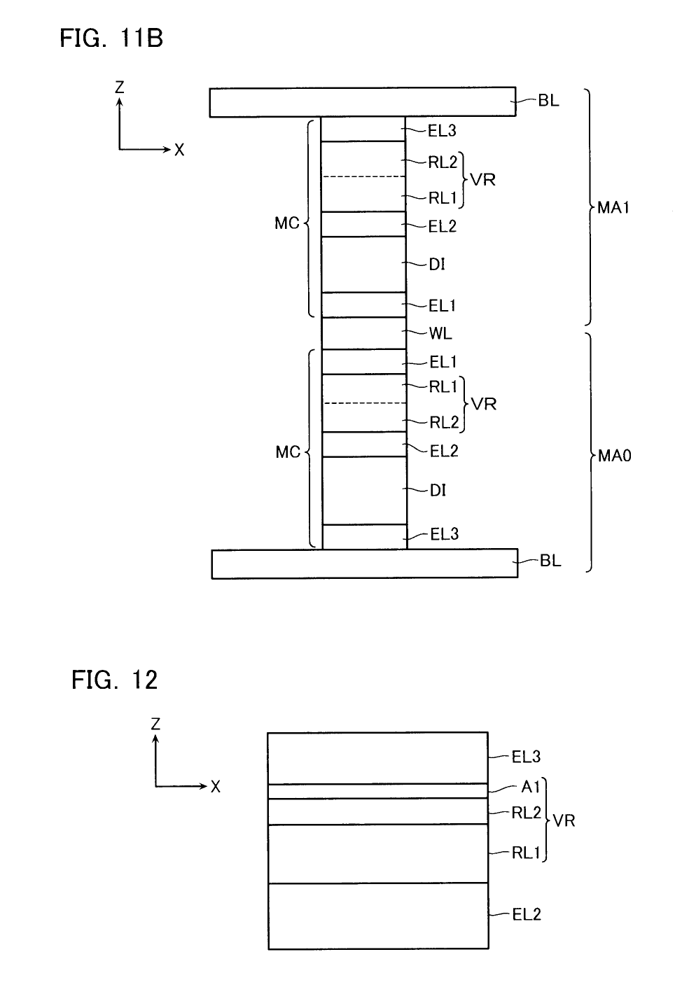

FIGS. 11A and 11B are cross-sectional views illustrating the cell array layers MA0 and MA1 of the memory cell array 1 having the three-dimensional structure illustrated in FIG. 10. In the structure, current flows from the bit line BL to the word line WL through the memory cell MC in the reset operation. In the set operation, current may flow from the word line WL to the bit line BL through the memory cell MC (bipolar operation), or current may flow from the bit line BL to the word line WL through the memory cell MC (unipolar operation). As illustrated in FIG. 11A, the memory cell MC including the second recording layer RL2 may be provided only in the layer (cell array layer MA1) in which the bit line BL is formed on the upper side and the word line WL is formed on the lower side in the Z direction. In this case, in the layer (cell array layer MA0) in which the bit line BL is formed on the lower side and the word line WL is formed on the upper side in the Z direction, the memory cell MC including only the first recording layer RL1 in which the amount of oxygen on the lower side in the Z direction is smaller than that on the upper side may be provided. The memory cell including only the first recording layer RL1 may be formed by, for example, a manufacturing method in which a metal film is deposited and then oxidized. As illustrated in FIG. 11B, the memory cell MC may be formed so that the second recording layer RL2 with a small amount of oxygen is provided close to the bit line BL, regardless of the stacked order of the bit line BL and the word line WL. In the both structures illustrated in FIGS. 11A and 11B, in the variable resistors VR of the memory cells MC in the cell array layer MA0 and the cell array layer MA1, the less amount of oxygen exists in the lower part or the upper part of the variable resistor VR which is close to the bit line BL. As a result, it is possible to improve the data retention characteristics of the memory cell MC in any cell array layer MA, regardless of the stacked order of the bit line BL and the word line WL.

### Second Embodiment

Next, a second embodiment of the invention will be described with reference to FIG. 12. The entire configuration of a semiconductor memory device according to this embodiment is the same as that of the semiconductor memory device according to the first embodiment and thus the detailed description thereof will be omitted. In addition, components having the same configurations as those in the first embodiment are denoted by the same reference numerals and the redundant description thereof will be omitted. FIG. 12 is a cross-sectional view illustrating the configuration of a variable resistor VR according to this embodiment.

As illustrated in FIG. 12, the variable resistor VR according to this embodiment includes a first recording layer RL1 made of a metal oxide and a second recording layer RL2 made of the same metal material as that forming the first recording layer RL1. The variable resistor VR according to this embodiment differs from the variable resistor VR in the first embodiment in the following point: an additional layer A1 which tends to deoxidize the second recording layer RL2 is inserted between the second recording layer RL2 and the electrode EL3. The deoxidizing layer A1 may be made of a deoxidizing element, such as titanium (Ti) or cobalt (Co). The deoxidizing layer A1 is provided in order to remove excess oxygen in the second recording layer RL2.

[Method of Manufacturing Variable Resistor VR]

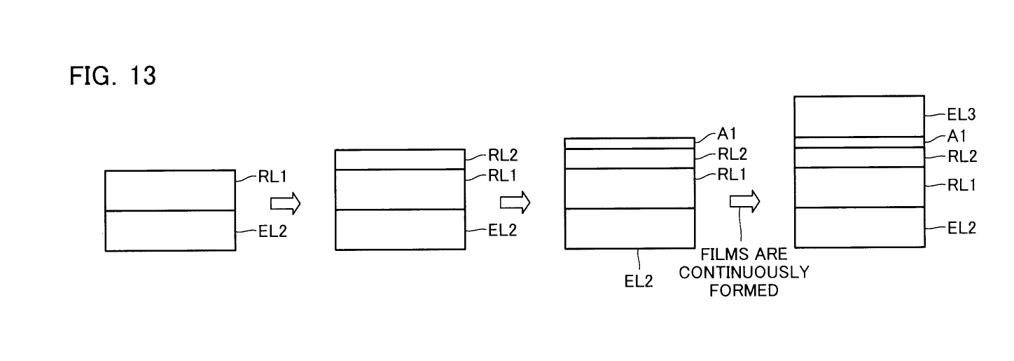

Next, a method of manufacturing the variable resistor VR will be described with reference to FIG. 13. FIG. 13 is a diagram illustrating the method of manufacturing the variable resistor VR according to this embodiment. First, a word line WL, electrodes EL1 and EL2, and a diode DI below the variable resistor VR are sequentially deposited by a known semiconductor device manufacturing method, and a certain stacked structure is formed (not illustrated). Then, the first recording layer RL1 and the second recording layer RL2 are sequentially formed on the electrode EL2. At that time, the first recording layer RL1 and the second recording layer RL2 are not necessarily formed continuously in the same atmosphere. Then, the deoxidizing layer A1 made of, for example, titanium (Ti) or cobalt (Co) and an electrode EL3 are formed continuously on the second recording layer RL2 in the same atmosphere so as not to be affected by an external environment, such as a manufacturing environment. Then, a bit line BL is formed thereon by a known semiconductor device manufacturing method, and a certain stacked structure is formed (not illustrated).

[Effect of Variable Resistor VR]

The variable resistor VR according to this embodiment includes the second recording layer RL2 made of the same metal material as that forming the first recording layer RL1. In the memory cell MC according to this embodiment, by providing the second recording layer RL2 made of a metal material, an upper part of the variable resistor VR which is close to the bit line BL contains small amount of oxygen. As a result, the data retention characteristics of the memory cell MC is improved. In addition, the formation of the deoxidizing layer A1 makes it possible to remove oxygen which may be introduced into the second recording layer RL2 when the second recording layer RL2 is exposed to the atmosphere in a manufacturing process. The deoxidization of the second recording layer RL2 leads to the further reduction of the oxygen amount of the upper part of the variable resistor VR which is close to the bit line BL, resulting in the further improvement of the data retention characteristics.

### Third Embodiment

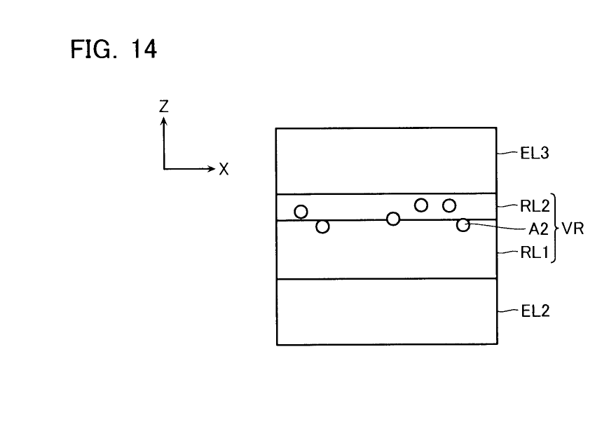

Next, a third embodiment of the invention will be described with reference to FIG. 14. The entire configuration of a semiconductor memory device according to this embodiment is the same as that of the semiconductor memory device according to the first embodiment and thus the detailed description thereof will be omitted. In addition, components having the same configurations as those in the first embodiment are denoted by the same reference numerals and the redundant description thereof will be omitted. FIG. 14 is a cross-sectional view illustrating the configuration of a variable resistor VR according to this embodiment.

As illustrated in FIG. 14, the variable resistor VR according to this embodiment includes a first recording layer RL1 made of a metal oxide and a second recording layer RL2 made of the same metal material as that forming the first recording layer RL1. The variable resistor VR according to this embodiment differs from the variable resistor VR according to the first embodiment in the following point: nano-structures A2 made of a deoxidizing element are formed in the first recording layer RL1 and the second recording layer RL2. The nano-structure A2 may be made of a deoxidizing element, such as a titanium oxide (TiOₓ) or a cobalt oxide (CoOₓ).

[Method of Manufacturing Variable Resistor VR]

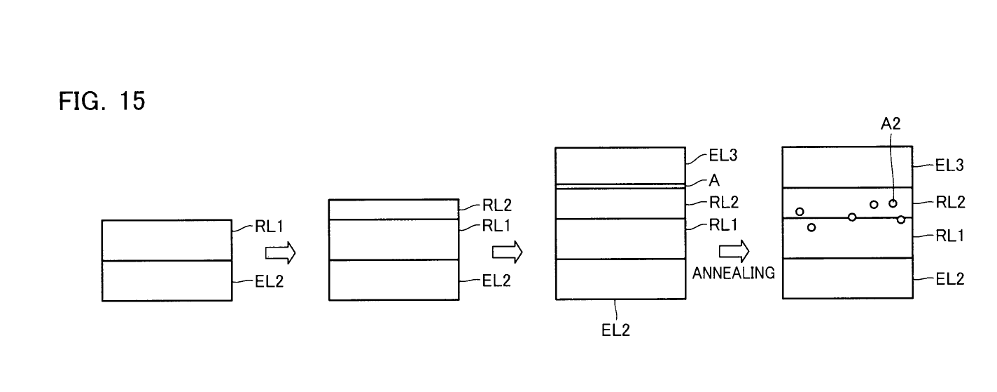

Next, a method of manufacturing the variable resistor VR will be described with reference to FIG. 15. FIG. 15 is a diagram illustrating the method of manufacturing the variable resistor VR according to this embodiment. First, a word line WL, electrodes EL1 and EL2, and a diode DI below the variable resistor VR are sequentially deposited by a known semiconductor device manufacturing method, and a certain stacked structure is formed (not illustrated). Then, the first recording layer RL1 and the second recording layer RL2 are sequentially formed on the electrode EL2. At that time, the first recording layer RL1 and the second recording layer RL2 are not necessarily formed continuously in the same atmosphere. Then, a deoxidizing layer A made of, for example, titanium (Ti) or cobalt (Co) and an electrode EL3 are continuously formed on the second recording layer RL2. Then, annealing is performed to form the nano-structures A2 of the deoxidizing element in the first recording layer RL1 and the second recording layer RL2. Then, a bit line BL is formed thereon by a known semiconductor device manufacturing method, and a certain stacked structure is formed (not illustrated).

### [Effect of Variable Resistor VR]

The variable resistor VR according to this embodiment includes the second recording layer RL2 made of the same metal material as that forming the first recording layer RL1. In the memory cell MC according to this embodiment, by providing the second recording layer RL2 made of a metal material, an upper part of the variable resistor VR which is close to the bit line BL contains small amount of oxygen. As a result, the data retention characteristics of the memory cell MC is improved. In addition, the formation of the nano-structures A2 made of the deoxidizing element makes it possible to remove oxygen which is introduced into the second recording layer RL2 due to exposure to the atmosphere in a manufacturing process. The deoxidization of the second recording layer RL2 leads to the further reduction of the oxygen amount of the upper part of the variable resistor VR which is close to the bit line BL, resulting in the further improvement of the data retention characteristics. Furthermore, since the deoxidizing element is the nano-structures A2, not the film, an unwanted voltage drop in the deoxidizing element may be avoided.

[Another Example of Manufacturing Method]

The embodiments of the invention are described above, but the invention is not limited thereto. For example, various changes, additions, and combinations can be made without departing from the scope and spirit of the invention. For example, in the manufacturing method according to the first embodiment, the electrode EL2, the first recording layer RL1, the second recording layer RL2, and the electrode EL3 are sequentially deposited. However, the variable resistor VR according to the first embodiment may be formed by the following manufacturing method.

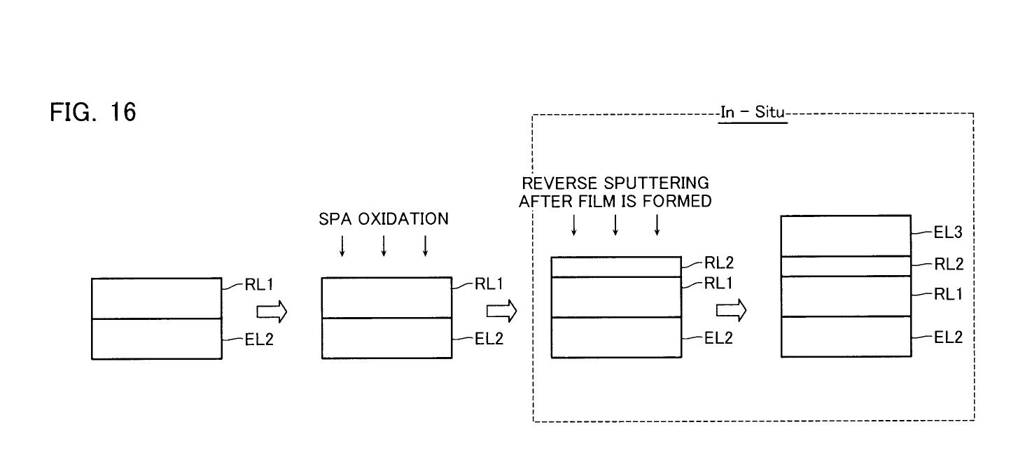

FIG. 16 is a diagram illustrating another example of the method of manufacturing the variable resistor VR. First, a word line WL, electrodes EL1 and EL2, and a diode DI below the variable resistor VR are sequentially deposited by a known semiconductor device manufacturing method, and a certain stacked structure is formed (not illustrated). Then, a metal film which will be a first recording layer RL1 is formed on the electrode EL2. Then, the metal film is oxidized to form the first recording layer RL1 made of a metal oxide.

Then, a metal film which will be a second recording layer RL2 is deposited on the first recording layer RL1. After that, sputtering by using an inert element is performed on the metal film to form the second recording layer RL2. For example, argon is used as the inert element. Then, an electrode EL3 is formed on the second recording layer RL2. Here, the sputtering of the second recording layer RL2 by using the inert element and the formation of the electrode EL3 are continuously performed in the same atmosphere so as not to be affected by an external environment, such as a manufacturing environment. In a manufacturing process according to this embodiment, when the semiconductor wafer is taken out from a manufacturing apparatus after depositing the metal film which will be the second recording layer RL2, the semiconductor wafer is exposed to the air in a manufacturing environment, and the metal film which will be the second recording layer RL2 is oxidized by oxygen in the air. However, sputtering of the metal film may remove the oxidized surface of the metal film which will be the second recording layer RL2. Therefore, it is possible to form the second recording layer RL2 with a small amount of oxygen. Then, a bit line BL is formed thereon by a known semiconductor device manufacturing method, and a certain stacked structure is formed (not illustrated). The variable resistor VR according to the first embodiment can also be manufactured by this manufacturing method.

### Fourth Embodiment

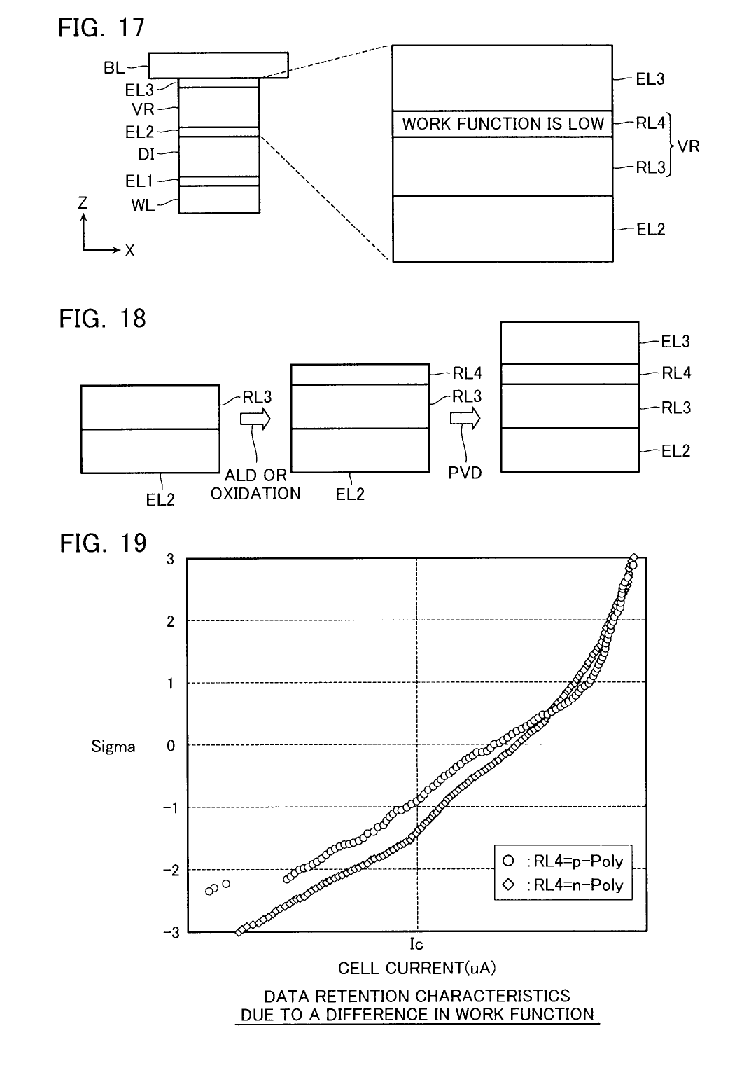

Next, a fourth embodiment of the present invention will be described with reference to FIG. 17. The entire configuration of a semiconductor memory device according to this embodiment is the same as that of the semiconductor memory device according to the first embodiment and thus the detailed description thereof will be omitted. In addition, components having the same configurations as those in the first embodiment are denoted by the same reference numerals and the redundant description thereof will be omitted. FIG. 17 is a cross-sectional view illustrating the configuration of a variable resistor VR according to this embodiment. This embodiment differs from the above-described embodiments in that metal materials used for two recording layers forming the variable resistor VR differs from each other.

[Variable Resistor VR]

FIG. 17 is a cross-sectional view illustrating the configuration of the memory cell MC and the variable resistor VR according to the embodiment. As described above, the memory cell MC includes a current rectifying element, such as a diode DI, the variable resistor VR, and electrodes EL1 to EL3 connected in series.

As illustrated in FIG. 17, the variable resistor VR according to this embodiment includes a third recording layer RL3 made of a metal oxide and a fourth recording layer RL4 made of a metal material (which may be different from that used for the third recording layer RL3). Here, the workfunction of the fourth recording layer RL4 is smaller than that of the third recording layer RL3. In the variable resistor VR, the fourth recording layer RL4 made of metal material is formed closer to the bit line BL, comparing to the third recording layer RL3. The fourth recording layer RL4 is connected to the bit line BL through the electrode EL3. As described above, the electrodes EL2 and EL3 are formed above and below the variable resistor VR, respectively. The electrode EL3 is connected to the upper bit line BL and the electrode EL2 is connected to a word line WL through the lower diode DI. The electrodes EL2 and EL3 may be made of, for example, a titanium nitride (TiN).

The third recording layer RL3 may be made of a metal oxide, such as a hafnium oxide (HfOₓ). The fourth recording layer RL4 may be made of a metal material, such as lanthanum (La) (workfunction: 2.3 eV). In other examples, the third recording layer RL3 may be made of a metal oxide, such as a hafnium oxide (HfOₓ), a manganese dioxide (MnO₂), a titanium oxide (TiOₓ), a niobium oxide (NbOₓ), alumina (Al₂O₃), an aluminum oxide (AlOₓ), a nickel oxide (NiO), or a tungsten oxide (WO). The fourth recording layer RL4 may be made of a metal material, such as cesium (Cs) (workfunction: 1.9 eV), strontium (Sr) (workfunction: 2.0 eV to 2.5 eV), hafnium (Hf) (workfunction: 3.9 eV), niobium (Nb) (workfunction: 4.0 eV), titanium (Ti) (workfunction: 4.1 eV), aluminum (Al) (workfunction: 4.1 eV), tantalum (Ta) (workfunction: 4.1 eV), cobalt (Co) (workfunction: 4.4 eV), or n+ polysilicon (workfunction: 4.0 eV). Hereafter, for simplicity of the explanation, doped-polysilicon is referred to as metal as long as it is used as the fourth recording layer RL4.

In general, large workfunction leads to the larger discontinuity of the conduction band edge between the third recording layer RL3 and the fourth recording layer RL4, which may reduce the unwanted leakage current. Since the requirement for workfunction is opposite in terms of the reduction of the leakage current and the improvement of the data retention characteristics, the value of workfunction may be decided depending on the specification of the memory device. Therefore, it is preferable that the material forming the fourth recording layer RL4 have the workfunction less than the workfunction of p+ polysilicon (5.2 eV), because the workfunction (electron-affinity) may be modified precisely by changing the kind and amount of doped impurities in polysilicon from 4.0 to 5.2 eV so that many choices of workfunction value can be provided.

[Method of Manufacturing Variable Resistor VR]

Next, a method of manufacturing the variable resistor VR will be described with reference to FIG. 18. FIG. 18 is a diagram illustrating the method of manufacturing the variable resistor VR according to this embodiment. First, the word line WL, the electrodes EL1 and EL2, and the diode DI below the variable resistor VR are sequentially deposited by a known semiconductor device manufacturing method, and a certain stacked structure is formed (not illustrated). Then, the third recording layer RL3 and the fourth recording layer RL4 are sequentially formed on the electrode EL2. At that time, the third recording layer RL3 may be formed by, for example, an atomic layer deposition (ALD) method. In addition, deposition of a metal film followed by an oxidation anneal may be used to form the third recording layer RL3. The fourth recording layer. RL4 may be formed by, for example, a physical vapor deposition (PVD) method. Then, the electrode EL3 and the bit line BL are sequentially formed on the fourth recording layer RL4 by the known semiconductor device manufacturing method, and a certain stacked structure is formed (not illustrated).

[Effect of Variable Resistor VR]

During a set operation, an oxygen vacancy (hereinafter, referred to as Vo) is generated in the variable resistor VR, and a chain of the oxygen vacancy (often called a filament) acts as a current path. As a result, the resistance value of the variable resistor VR becomes small. When the oxygen vacancy Vo in the variable resistor VR is diffused by heat for example, the state of the filament (conductive path) is changed, and the resistance value of the variable resistor VR is changed. Therefore, in order to keep the resistance value of the variable resistor VR being unchanged, it is necessary to prevent the diffusion of the oxygen vacancy Vo in the variable resistor VR.

There are two kinds of oxygen vacancy Vo: one is an oxygen vacancy Vo which is electrically neutral, and the other is an oxygen vacancy Vo²⁺ which has the two positive charges. Following to the results of first principle calculations and so on, it has been pointed out that the charged oxygen vacancy Vo²⁺ in a metal oxide film is more likely to be diffused, comparing to the neutral oxygen vacancy Vo. Therefore, it is expected that the data retention characteristics is improved, when the oxygen vacancy in the variable resistor VR is kept electrically neutral and the diffusion of the oxygen vacancy is suppressed.

Following to the results of first principle calculations and so on, it has also been reported that electrical state of the oxygen vacancy in a metal oxide film (electrically neutral or being charged) depends on the position of the Fermi level of the metal oxide film. Thus, it is expected that when the Fermi level of the third recording layer RL3 is high, the oxygen vacancy in the variable resistor VR is likely to become electrically neutral. On the other hand, when the Fermi level of the third recording layer RL3 is low, the oxygen vacancy in the variable resistor VR is likely to be a charged oxygen vacancy Vo²⁺. Based on the scientific reports mentioned above, it is expected that the data retention characteristics is improved by keeping the Fermi level of the third recording layer RL3 high. And this may be possible when the metal having the small workfunction is contacted to the third recording layer RL3.

FIG. 19 is a graph illustrating the data retention characteristics of the memory cell according to the fourth embodiment. The graph illustrated in FIG. 19 is a sigma plot of the cell current measured when the read voltage is applied to the memory cell MC. Here, the cell current was measured after a few minutes have elapsed since the last set operation. In FIG. 19, the cell current of the two different structures having n+ polysilicon or p+ polysilicon as the fourth recording layer RL4 are compared. In FIG. 19, a circle denotes the cell current of the structures having p+ polisilicon as the fourth recording layer RL4, whereas a diamond denotes the cell current of the structures having n+ polisilicon as the fourth recording layer RL4. Just after the set operation, the cell current was equal to or greater than a criteria current Ic. After a few minutes, however, the cell current of some cells becomes lower than the criteria current Ic. The amount of the cell current reduction is different when the different polisilicon type is used as the fourth recording layer RL4. When the fourth recording layer RL4 is made of p+ polysilicon, the number of memory cells in which a cell current becomes smaller than the criteria current Ic after a few minutes is larger, comparing to the case where the fourth recording layer RL4 is made of n+ polysilicon. The difference is possibly caused by the difference of the workfunctions of the fourth recording layer RL4: 5.2 eV for the p+ polysilicon and 4.0 eV for the n+ polysilicon. When the fourth recording layer RL4 is made of p+ polysilicon, the Fermi level of the third recording layer RL3 is lowered, comparing to the case where the fourth recording layer RL4 is made of n+ polysilicon. Therefore, more number of electrically charged oxygen vacancy Vo2+, which is easy to diffuse, is generated in the third recording layer RL3, and as a results the data retention characteristics is worse, when the fourth recording layer RL4 is made of p+ polysilicon.

In this embodiment, the fourth recording layer RL4 which is provided so as to contact with the third recording layer RL3 is made of a metal material having a workfunction less than the third recording layer RL3. In this configuration of the present embodiment, it is possible to increase the Fermi level of the third recording layer RL3 and thus prevent the charged oxygen vacancy Vo²⁺ being formed in the variable resistor VR. Therefore, the data retention characteristics of the variable resistor VR is improved in this embodiment.

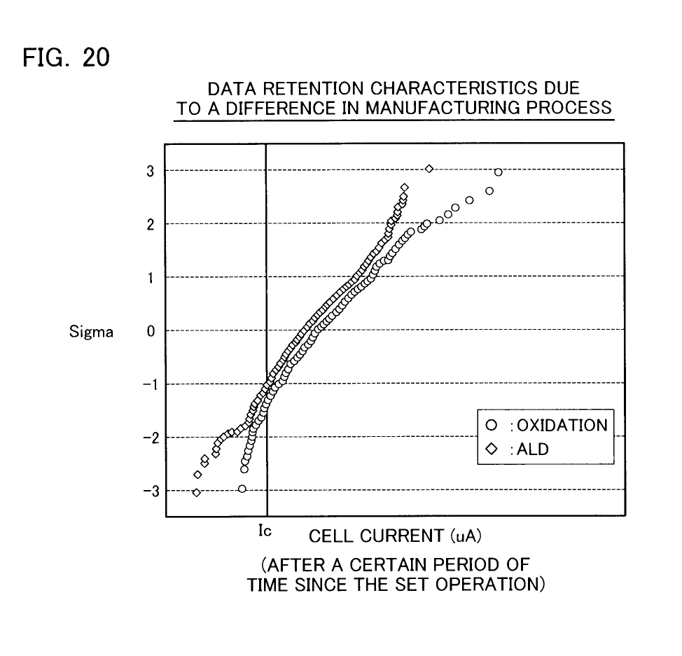

FIG. 20 is a graph illustrating the data retention characteristics of the memory cell according to the fourth embodiment. The graph illustrated in FIG. 20 is a sigma plot of the cell current measured when a read voltage is applied to the memory cell MC. Here, the cell current was measured after a few minutes have elapsed since the last set operation. In FIG. 20, the cell current of the two different structures fabricated by the two different methods are compared. In one structure, the third recording layer RL3 is formed by using a metal deposition followed by an oxidation (hereinafter may be described as Type-A). On the other structure, the third recording layer RL3 is formed by using ALD method (hereinafter may be described as Type-B). In FIG. 20, a circle denotes the cell current of the structure Type-A, and a diamond denotes the cell current of the structures Type-B. Just after the set operation, the cell current was equal to or greater than a criteria current Ic. After a few minutes, however, the cell current of some cells becomes lower than the criteria current Ic. As shown in FIG. 20, the amount of the cell current reduction is larger in the structure Type-B, comparing to the structure Type-A. In general, ALD process provides the well-control of local composition of materials. On the contrary, when the third recording layer RL3 is formed by a metal deposition followed by an oxidation, oxygen amount in the bottom region of the third recording layer RL3 tends to be small, because oxidation occurs from the top surface of the third recording layer RL3. Thus, metal-rich region of the third recording layer RL3 may act as the fourth recording layer RL4 (Hf in this case), and the data retention characteristics is better in the structure Type-A. This experimental results supports the validity of our model where keeping the electrical state of oxygen vacancy neutral by Fermi-level-tuning improves the data retention characteristics.

The experimental results for the comparison of fabrication method of the third recording layer RL3 is mentioned above to support our discussion, not to intend to limit the fabrication method of the third recording layer RL3. In some application, it may be preferable to select the ALD method, since the ALD method can reduce the thickness fluctuation of the third recording layer RL3.

[Other Examples of Memory Cell Array]

Similarly to the above-described embodiments, a plurality of memory cell structures according to this embodiment may be stacked in the Z direction to form a three-dimensional structure.

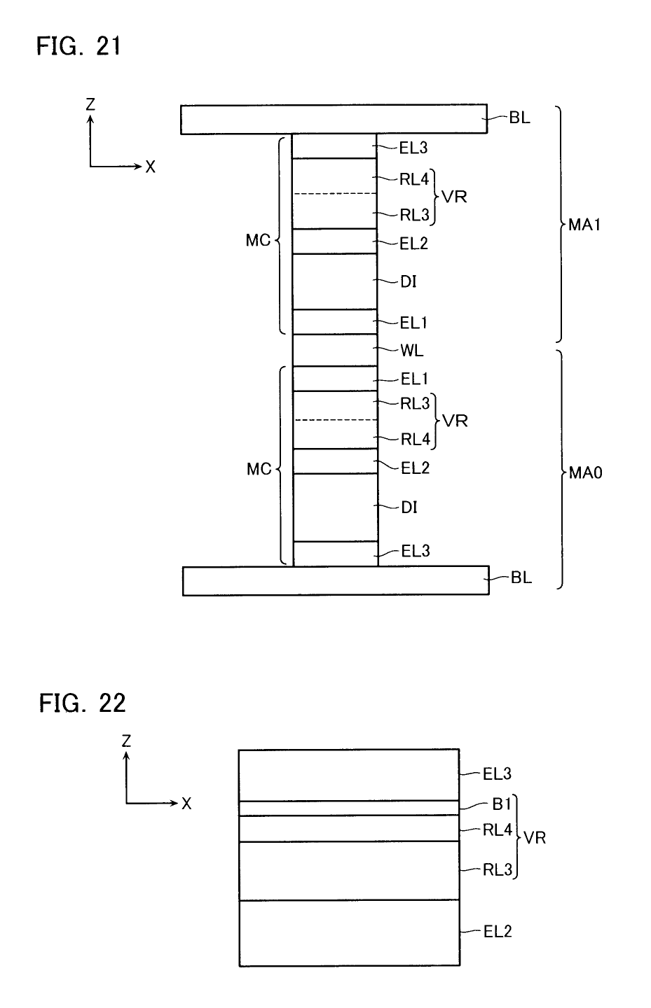

FIG. 21 is a cross-sectional view illustrating cell array layers MA0 and MA1 of the memory cell array 1 having the three-dimensional structure illustrated in FIG. 10. In the structure, a current flows from the bit line BL to the word line WL through the memory cell MC in the reset operation. In the set operation, a current may flow from the word line WL to the bit line BL through the memory cell MC (bipolar operation), or a current may flow from the bit line BL to the word line WL through the memory cell MC (unipolar operation). In the present embodiment, as illustrated in FIG. 21, the memory cell MC may be formed such that the fourth recording layer RL4 is provided close to the bit line BL, regardless of the positional relationship between the bit line BL and the word line WL in the vertical direction. In the structure illustrated in FIG. 21, it is possible to increase the Fermi level of the third recording layer RL3 of the variable resistor VR in each of the memory cells MC provided in the cell array layer MA0 and the cell array layer MA1, and prevent the charged oxygen vacancy Vo²⁺ being formed in the variable resistor VR. As a result, it is possible to improve the data retention characteristics of the memory cell MC in any cell array layer MA, regardless of the positional relationship between the bit line BL and the word line WL in the Z direction.

### Fifth Embodiment

Next, a fifth embodiment of the present invention will be described with reference to FIG. 22. The entire configuration of a semiconductor memory device according to this embodiment is the same as that of the semiconductor memory device according to the first embodiment and thus the detailed description thereof will be omitted. In addition, components having the same configurations as those in the first embodiment are denoted by the same reference numerals and the redundant description thereof will be omitted. FIG. 22 is a cross-sectional view illustrating the configuration of a variable resistor VR according to this embodiment.

As illustrated in FIG. 22, the variable resistor VR according to this embodiment includes a third recording layer RL3 made of a metal oxide and a fourth recording layer RL4 made of a metal whose material is different from that forming the third recording layer RL3. The variable resistor VR according to this embodiment differs from the variable resistor VR according to the fourth embodiment in the following point: a polysilicon (Poly-Si) layer B1 is formed between the fourth recording layer RL4 and the electrode EL3. The polysilicon layer B1 may contain impurities inside so as to be conductive. The impurity may be, for example, boron (B), phosphorus (P), arsenic (As), and conductivity type of polysilicon (n-type or p-type) depends on the kind and amount of impurities.

### [Method of Manufacturing Variable Resistor VR]

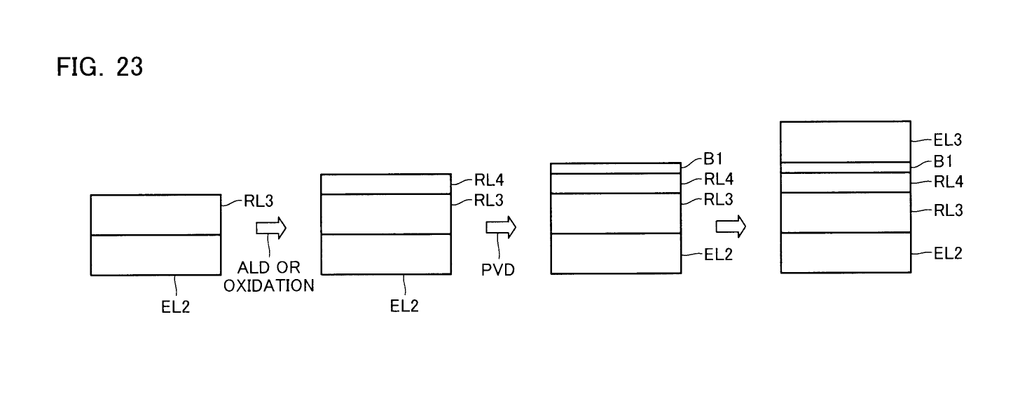

Next, a method of manufacturing the variable resistor VR will be described with reference to FIG. 23. FIG. 23 is a diagram illustrating the method of manufacturing the variable resistor VR according to this embodiment. First, a word line WL, electrodes EL1 and EL2, and a diode DI below the variable resistor VR are sequentially deposited by a known semiconductor device manufacturing method, and a certain stacked structure is formed (not illustrated). Then, the third recording layer RL3 and the fourth recording layer RL4 are sequentially formed on the electrode EL2. At that time, the third recording layer RL3 may be formed by, for example, an atomic layer deposition (ALD) method. Alternatively, a metal film deposition followed by an oxidation is used to form the third recording layer RL3. The fourth recording layer RL4 may be formed by, for example, a physical vapor deposition (PVD) method. Then, the polysilicon layer B1 and the electrode EL3 are formed on the fourth recording layer RL4. Then, a bit line BL is formed thereon by a known semiconductor device manufacturing method, and a certain stacked structure is formed (not illustrated).

[Effect of Variable Resistor VR]

The variable resistor VR according to this embodiment includes the fourth recording layer RL4 made of a metal whose material is different from that forming the third recording layer RL3. In the memory cell MC according to this embodiment, by forming the fourth recording layer RL4 made of a metal material whose workfunction is small, it is possible to prevent the electrically charged oxygen vacancy Vo²⁺ being formed in the variable resistor VR. As a result, it is possible to improve the data retention characteristics of the memory cell MC.

### Sixth Embodiment

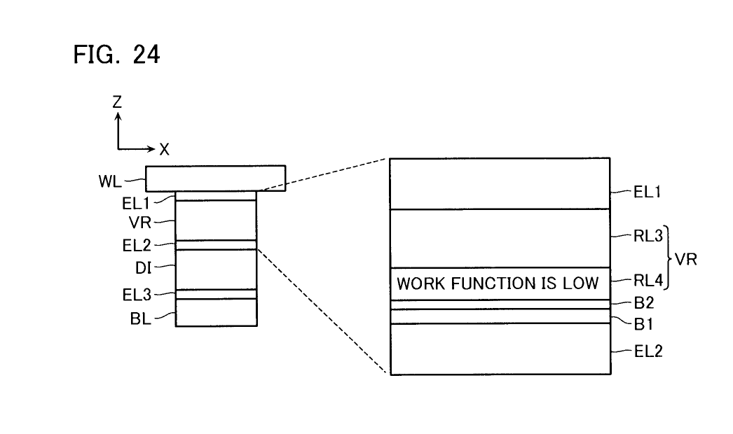

Next, a sixth embodiment of the invention will be described with reference to FIG. 24. The entire configuration of a semiconductor memory device according to this embodiment is the same as that of the semiconductor memory device according to the first embodiment and thus the detailed description thereof will be omitted. In addition, components having the same configurations as those in the first embodiment are denoted by the same reference numerals and the redundant description thereof will be omitted. FIG. 24 is a cross-sectional view illustrating the configuration of a variable resistor VR according to this embodiment. FIG. 24 shows a state in which a word line WL is formed at the upper part of the memory cell MC and a bit line BL is formed at the lower part thereof.

As illustrated in FIG. 24, the variable resistor VR according to this embodiment includes a third recording layer RL3 made of a metal oxide and a fourth recording layer RL4 made of a metal whose material is different from that forming the third recording layer RL3. The variable resistor VR according to this embodiment differs from the variable resistor VR according to the fourth embodiment in the following point: a polysilicon layer B1 and a silicide prevent layer B2 are provided between the fourth recording layer RL4 and the electrode EL2. The silicide prevent layer B2 may be a silicon oxynitride (SiON) film or a silicon oxide (SiO) film. The silicide prevent layer B2 prevents for the fourth recording layer RL4 to generate the silicide with the polysilicon layer B1 and.

[Method of Manufacturing Variable Resistor VR]

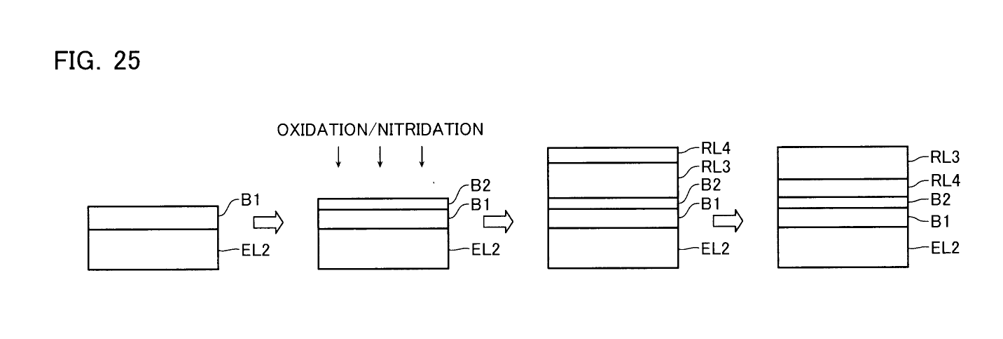

Next, a method of manufacturing the variable resistor VR will be described with reference to FIG. 25. FIG. 25 is a diagram illustrating the method of manufacturing the variable resistor VR according to this embodiment. First, a bit line BL, electrodes EL3 and EL2, and a diode DI below the variable resistor VR are sequentially deposited by a known semiconductor device manufacturing method, and a certain stacked structure is formed (not illustrated). Then, the polysilicon layer B1 is formed on the electrode EL2. Then, the polysilicon layer B1 is oxidized/nitrided to form the silicide prevent layer B2 which is a silicon oxide film or a silicon oxynitride film. Then, the third recording layer RL3 and the fourth recording layer RL4 are sequentially formed thereon. At that time, the fourth recording layer RL4 is formed on the third recording layer RL3. However, the fourth recording layer RL4 is diffused into the third recording layer RL3 by annealing process. As a result, the fourth recording layer RL4 is formed so as to contact with the silicide prevent layer B2. In this case, the diffusion of the fourth recording layer RL4 is stopped by the silicide prevent layer B2 and does not affect, for example, to the polysilicon layer B1. The electrode EL1 and the word line WL are sequentially formed on the third recording layer RL3 by a known semiconductor device manufacturing method, and a certain stacked structure is formed (not illustrated).

[Effect of Variable Resistor VR]

The variable resistor VR according to this embodiment includes the fourth recording layer RL4 made of a metal whose material is different from that forming the third recording layer RL3. In the memory cell MC according to this embodiment, by forming the fourth recording layer RL4 made of a metal material whose workfunction is small, it is possible to prevent the electrically charged oxygen vacancy Vo²⁺ being formed in the variable resistor VR. As a result, it is possible to improve the data retention characteristics of the memory cell MC.

In addition, the variable resistor VR according to this embodiment includes the silicide prevent layer B2 so as to avoid the generation of silicide between the polysilicon layer B1 and the fourth recording layer RL4. Therefore, workfunction of the fourth recording layer RL4 is not modified by the silicidation. According to the manufacturing method of this embodiment, the fourth recording layer RL4 is formed after the third recording layer RL3 is formed. This manufacturing process can be preferable, because the fourth recording layer RL4 may be inserted between the silicide prevent layer B2 and the third recording layer RL3 in a not-oxidized form. Otherwise (if the fourth recording layer RL4 is formed, and then the third recording layer RL3 is formed thereon), the fourth recording layer RL4 may be oxidized by air when the surface of the fourth recording layer RL4 is exposed to the manufacturing environment, prior to formation of the third recording layer RL3.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a plurality of first lines provided on a substrate;
a plurality of second lines provided between the first lines and the substrate so as to intersect the first lines; and
a first memory cell array including first memory cells, each of the first memory cells being provided at respective intersections of the first lines and the second lines and including a current rectifying element and a variable resistor connected in series,
the variable resistor of the first memory cell including a first recording layer and a second recording layer, the first recording layer being made of an oxide of a first metal material, the second recording layer being made of the first metal material and being formed so as to contact with the first recording layer, and
the second recording layer being closer to the first line than the first recording layer is.

2. The semiconductor memory device according to claim 1,
wherein the amount of oxygen per unit volume in a lower region of the first recording layer in a direction perpendicular to the substrate is smaller than that in an upper region of the first recording layer in the direction.

3. The semiconductor memory device according to claim 2,
wherein the first lines and the second lines are alternately stacked in the direction perpendicular to the substrate,
among the first lines and the second lines, a second memory cell array including second memory cells is formed between the first lines which are formed on a lower side so as to be close to the substrate and the second lines which are formed on an upper side, each of the second memory cells being provided at respective intersections of the first lines and the second lines and including a current rectifying element and a variable resistor connected in series, and
the variable resistor of the second memory cell includes only the first recording layer made of the oxide of the first metal material.

4. The semiconductor memory device according to claim 2,
wherein the first lines and the second lines are alternately stacked in the direction perpendicular to the substrate,
among the first lines and the second lines, a second memory cell array including second memory cells is formed between the first lines which are formed on a lower side so as to be close to the substrate and the second lines which are formed on an upper side, each of the second memory cells being provided at respective intersections of the first lines and the second lines and including a current rectifying element and a variable resistor connected in series,
the variable resistor of the second memory cell includes a first recording layer and a second recording layer, the first recording layer being made of an oxide of a first metal material, the second recording layer being made of the first metal material and being formed so as to contact with the first recording layer, and
the second recording layer is closer to the first line than the first recording layer is.

5. The semiconductor memory device according to claim 1, further comprising:
a deoxidizing layer formed so as to contact with the second recording layer, the deoxidizing layer deoxidizing the second recording layer.

6. The semiconductor memory device according to claim 1, further comprising:
a nano-structure of a deoxidizing element formed in the first recording layer and the second recording layer, the nano-structure of the deoxidizing element deoxidizing the second recording layer.

7. The semiconductor memory device according to claim 1,
wherein a current is rectified by the current rectifying element in a direction in which the current flows from the first line to the second line through a selected first memory cell in a reset operation.

8. A method of manufacturing a semiconductor memory device, comprising:
forming a plurality of third lines to be bit lines or word lines;
forming memory cells having a current rectifying element and a variable resistor connected in series on the third line so as to be electrically connected to the third lines; and
forming a plurality of fourth lines to be the bit lines or the word lines, on the memory cells, the fourth lines being electrically connected to the memory cells and intersecting the third lines, each of the memory cells being arranged at respective intersections of the third lines and the fourth lines,
in the forming of the memory cell, the variable resistor being formed to include a first recording layer and a second recording layer, the first recording layer being made of an oxide of a first metal material, the second recording layer being made of the first metal material and being formed so as to contact with the first recording layer, and
the second recording layer being provided in a portion of the variable resistor closer to one of the third line and the fourth line which becomes a bit line during an operation than the first recording layer is provided.

9. The method of manufacturing a semiconductor memory device according to claim 8,
wherein the first recording layer and the second recording layer are continuously formed.

10. The method of manufacturing a semiconductor memory device according to claim 8, further comprising:
forming a deoxidizing layer so as to contact with the second recording layer, the deoxidizing layer deoxidizing the second recording layer.

11. The method of manufacturing a semiconductor memory device according to claim 8, further comprising:
forming a nano-structure of a deoxidizing element in the first recording layer and the second recording layer, the nano-structure of the deoxidizing element deoxidizing the second recording layer.

12. The method of manufacturing a semiconductor memory device according to claim 11,
wherein the nano-structure of the deoxidizing element is formed by stacking a deoxidizing element and annealing the deoxidizing element.

13. The method of manufacturing a semiconductor memory device according to claim 8,
wherein sputtering is performed on the second recording layer after forming the second recording layer.

14. A semiconductor memory device comprising:
a plurality of first lines provided on a substrate;
a plurality of second lines provided between the first lines and the substrate so as to intersect the first lines; and
a first memory cell array including first memory cells, each of the first memory cells being provided at respective intersections of the first lines and the second lines and including a current rectifying element and a variable resistor connected in series,
the variable resistor of the first memory cell including a third recording layer and a fourth recording layer, the third recording layer being made of an oxide of a first metal material, the fourth recording layer being made of a second metal material having a workfunction less than that of the oxide of the first metal material and being formed so as to contact with the third recording layer, and
the fourth recording layer being closer to the first line than the third recording layer is.

15. The semiconductor memory device according to claim 14,
wherein the first lines and the second lines are alternately stacked in a direction perpendicular to the substrate,
among the first lines and the second lines, a second memory cell array including second memory cells is formed between the first lines which are formed on a lower side so as to be close to the substrate and the second lines which are formed on an upper side, each of the second memory cells being provided at respective intersections of the first lines and the second lines and including a current rectifying element and a variable resistor connected in series,
the variable resistor of the second memory cell includes a third recording layer and a fourth recording layer, the third recording layer being made of the oxide of the first metal material, the fourth recording layer being made of a second metal material having a workfunction less than that of the oxide of the first metal material and being formed so as to contact with the third recording layer, and
the fourth recording layer is closer to the first line than the third recording layer in the second memory cell is.

16. The semiconductor memory device according to claim 14, further comprising:
a polysilicon layer formed so as to contact with the fourth recording layer.

17. The semiconductor memory device according to claim 16, further comprising:
a silicon oxide film or a silicon oxynitride film being formed between the polysilicon layer and the fourth recording layer.

18. The semiconductor memory device according to claim 14,
wherein the second metal material has a smaller workfunction than p+ polysilicon.

19. The semiconductor memory device according to claim 14,
wherein a current is rectified by the current rectifying element in a direction in which the current flows from the first line to the second line through a selected first memory cell in a reset operation.
